(19) United States
(12) Patent Application Publication
(10) Pub. No.: US 2007/0147490 A1
(43) Pub. Date: Jun. 28, 2007

(54) Filter coefficient adjusting circuit

(76) Inventors: Kouji Okamoto, Osaka (JP); Hiroyuki Nakahiro, Kyoto (JP)

Correspondence Address: WENDEROTH, LIND & PONACK L.L.P., 2033 K. STREET, NW, SUITE 800, WASHINGTON, DC, 20006, US

(21) Appl. No.: 10/578,915

(22) PCT Filed: Nov. 9, 2004
(86) PCT No.: PCT/JP04/16575

§ 371 Date: May 9, 2006

(30) Foreign Application Priority Data
Nov. 11, 2003 (JP) 2003-381845

(51) Int. Cl. H03K 5/159; H04L 7/00

(52) U.S. Cl. 375/232; 375/371

(57) ABSTRACT

A filter coefficient adjusting circuit of the present invention comprises a coefficient adjusting circuit (2) that adjusts an equalization coefficient by weighting an initial value of the equalization coefficient on the left side from a center tap of a FIR filter (1) that equalizes a reproduce signal, by a factor of n, and weighting an initial value of the equalization coefficient on the right side by a factor of (2−n), and determines the factor n of the weighting so as to optimize an output of a jitter detector (5), for example, that detects jitter between the reproduced signal and a clock, as an equalization performance detecting means that detects an equalization performance of the reproduce signal. According to the filter coefficient adjusting circuit of the present invention, it is possible to simplify the control method as compared to conventional group delay correcting circuits, and optimize the group delay of the reproduced signal according to the characteristics of the reproduced signal without requiring any additional circuits, thereby improving the reproduction performance.

### TECHNICAL FIELD

The present invention relates to a recorded information reproducing apparatus that reproduces data from recording media such as optical discs employing a FIR (Finite Impulse Response) filter and, more particularly, to a filter coefficient adjusting circuit that corrects group delay distortion of reproduced signals by means of the FIR filter.

### BACKGROUND ART

FIG. 10 illustrates a common recorded information reproducing apparatus, taking a DVD as an example.

The recorded information reproducing apparatus as shown in FIG. 10 has a recording medium 111, an AGC (Automatic Gain Control) circuit 112, an analog equalizer filter 113, an offset adjusting circuit 114, an A/D converter 115, an adaptive FIR filter 116, a Viterbi decoder 117, and a PLL (Phase Locked Loop) circuit 118.

Functions of the respective components of the apparatus will be briefly described.

The AGC circuit 112 and the offset adjusting circuit 114 adjust the amplitude and offset of a reproduced signal so that characteristics of the reproduced signal fall within an input range of the A/D converter 115. The analog equalizer filter 113 performs noise reduction of the reproduced signal and a waveform equalization process (mainly boosting process) so that the characteristics of the reproduced signal match with the characteristics of the Viterbi decoder at the latter stage.

Reproduction data quantized by the A/D converter 115 are inputted to the adaptive FIR filter 116, and are subjected to correction of residual equalization errors. The adaptive FIR filter 116 employs adaptive equalization algorithm such as LMS (Least Mean Square), and performs an automatic adjustment process so that the tap coefficients are optimized.

The reproduced signal which is subjected to the waveform equalization process by the analog equalizer filter 113 and the FIR filter 116 is input to the Viterbi decoder 117, and detection of digital data that is recorded in the recording medium 111 is carried out. A clock synchronized with the data is extracted by the PLL circuit 118, utilizing the outputs from the A/D converter 115 and the adaptive FIR filter 116.

Further, in such a recording information reproduction apparatus, in order to reduce the area, a method of digitizing analog functions is raised. More specifically, as shown in FIG. 11, the noise reduction function and the waveform equalization function of the analog equalizer filter 113 shown in FIG. 10 are separated from each other, and the noise reduction function is provided in an analog low-pass filter 120, while the waveform equalization function (specifically, boosting function) is implemented in a digital equalizer filter 121 which is connected the A/D converter 115 at a next stage thereof. Such digitization of the analog function realizes a significant reduction in the analog area, greatly contributing to reduction in the system area.

In the recorded information reproducing apparatus as shown in FIG. 11, a further reduction in the analog area can be accomplished by realizing a function of correcting the group delay characteristics of the reproduced signal in a digital region as well as realizing the boosting function as a waveform equalization processing in a digital region. The function of correcting the group delay characteristics of the reproduced signal is required for the PLL circuit 118 which extracts clocks synchronized with data, to be operated using the reproduced signal, and this function can make the group delay characteristics of the reproduced signal which is inputted to the PLL circuit 118 flat, thereby suppressing the jitter performance of the PLL circuit 118.

As a conventional group delay adjusting method in such a system, there is a method of correcting filter coefficients on the basis of a difference value between an amplitude level of the equalized reproduced signal and an ideal level (for example, refer to Patent Document 1).

Patent Document 1: Japanese Unexamined Patent Publication No. 11-191202

However, the conventional recorded information reproducing apparatus shown in FIG. 11 has following problems, because it has a construction in which the tap coefficients of the digital equalizer filter 121 are set at asymmetric values, using a difference value between the output of the digital equalizer filter 121 and a corresponding ideal value so that the group delay characteristics of the reproduced signal that is inputted to the PLL circuit 118 becomes flat:

First, when it is attempted to have a loop construction that successively changes the tap coefficients of the digital equalizer filter 121 using the difference value between the output of the digital equalizer filter 121 and an ideal value, it is required for this loop and the PLL for extracting clocks to perform a double-loop operation, thereby resulting in a complicated control. In addition, by that the inputted reproduced signal is affected by the non-ideal factors other than the group delay, such as distortions or reproduction jitter, there may arise errors between the output of the digital equalizer filter 121 and the ideal value, influenced by those other than the group delays, thereby the jitter characteristics of the PLL circuit 118 may be deteriorated.

Secondly, when the tap coefficients are controlled perfectly independently for left and for right with respect to a center tap in a case where the tap coefficients of the digital equalizer filter 121 are controlled asymmetrically, the gain characteristics of the digital equalizer filter 121 also changes largely. This would require a function of correcting the gain characteristics separately.

The present invention is made to solve the above-mentioned problems, and has for its object to provide a filter coefficient adjustment circuit that can optimize group delay characteristics of a reproduced signal which is inputted to the PLL for extracting clocks.

### DISCLOSURE OF THE INVENTION

According to claim 1 of the present invention, there is provided a filter coefficient adjusting circuit which includes an FIR filter which makes an input signal subjected to a filtering process according to an equalization coefficient, a PLL which extracts a clock synchronized with the input signal using an output from the FIR filter, an equalization performance detecting unit which detects an equalization performance of the FIR filter, and an equalization coefficient determining unit which determines the equalization coefficient of the FIR filter according to an output value of the equalization performance detecting unit.

Therefore, it is possible to simplify the control within the circuit, and optimize the group delay of the input signal according to the characteristics of the input signal without providing additional circuits, thereby enhancing the reproduction performance.

According to claim 2 of the present invention, there is provided a filter coefficient adjusting circuit as defined in claim 1, wherein the equalization coefficient determining unit outputs a previously-set initial value as the equalization coefficient of the FIR filter before the PLL reaches the locked state.

Therefore, since the jitter value becomes stationary after the PLL has locked, it is possible to smoothly carry out a search for an optimum value for the equalization coefficient.

According to claim 3 of the present invention, there is provided an equalization coefficient adjusting circuit as defined in claim 1, wherein the equalization coefficient determining unit weights, while the tap coefficient of the FIR filter is an odd number, the initial value of the equalization coefficient at left with respect to a center tap of the FIR filter by a factor of n (n is a real number which is equal to 0 or larger and equal to 2 or smaller), and weights the initial value of the equalization coefficient at right by a factor of (2−n), and outputs the weighted value.

Therefore, it is possible to update the equalization coefficient without giving any changes to the gain characteristics of the FIR filter. Therefore, there is no need to provide a gain adjusting circuit as in the prior art.

According to claim 4 of the present invention, in the filter coefficient adjusting circuit as defined in claim 1, the equalization coefficient determining unit weights the initial value of the equalization coefficient on the left side from a center of a delay line of the FIR filter by a factor of n (n is a real number which is equal to 0 or larger and equal to 2 or smaller), and weights the initial value of the equalization coefficient on the right side by a factor of (2−n), wherein the number of taps in the FIR filter is an even number, and outputs the weighted value.

Therefore, it is possible to update the equalization coefficient without giving any changes to the gain characteristics of the FIR filter. Therefore, there is no need to provide a gain adjusting circuit as in the prior art.

According to claim 5 of the present invention, there is provided a filter coefficient adjusting circuit as defined in claim 3, wherein the value of weighting n is independently set for each pair consisting of two taps which are at equal distances from the center tap of the FIR filter.

Therefore, it is possible to finely adjust the group delay.

According to claim 6 of the present invention, there is provided a filter coefficient adjusting circuit as defined in claim 4, wherein the value of weighting n is independently set for each pair consisting of two taps which are at equal distances from the center of the delay line of the FIR filter.

Therefore, it is possible to finely adjust the group delay.

According to claim 7 of the present invention, there is provided a filter coefficient adjusting circuit as defined in any of claims 3 to 6, wherein the equalization coefficient determining unit determines an optimum output value of the equalization performance detecting unit, and determines the value of weighting n which provides an optimum output value of the equalization performance detecting unit.

Therefore, it is possible to easily determine the equalization coefficient.

According to claim 8 of the present invention, there is provided a filter coefficient adjusting circuit as defined in claim 7, wherein the equalization coefficient determining unit captures the output of the equalization performance detecting unit at variable time intervals, and determines the value of weighting n on the basis of the captured value.

Therefore, it is possible to adjust the equalization coefficient more accurately.

According to claim 9 of the present invention, there is provided a filter coefficient adjusting circuit as defined in claim 7, wherein the equalization coefficient determining unit establishes an upper limit and a lower limit and an update interval thereof, independently, for the value of weighting n, and determines the value of weighting n within a setting range.

Therefore, it is possible to finely set the asymmetry ratio.

According to claim 10 of the present invention, there is provided a filter coefficient adjusting circuit as defined in claim 7, wherein the equalization coefficient determining unit establishes an operation of detecting the value of weighting n which provides an optimum output value of the equalization performance detection unit on the basis of the operation setting control signal in accordance with the characteristics of the input signal.

Therefore, it is possible to perform an operation setting using, for example, a signal which has detected a defect in the input signal, or a gate signal which is dependent on the data format of the input signal.

### EFFECTS OF THE INVENTION

According to the filter coefficient adjusting circuit of the present invention, it is possible to simplify the control technique as well as optimize the group delay of the reproduced signal in accordance with the characteristics of the reproduced signal without requiring any additional circuits, thereby enabling to improve the reproduction performance.

### BRIEF DESCRIPTION OF THE DRAWINGS

FIG. 1(a) is a diagram illustrating a structure of a filter coefficient adjusting circuit according to the present invention.

FIG. 1(b) is a diagram showing a timing chart of a jitter detector.

FIG. 2 is a diagram illustrating a structure of an FIR filter.

FIG. 3 is a diagram illustrating a structure of a coefficient adjusting circuit according to the present invention.

FIG. 4 is a diagram showing gain characteristics of the FIR filter when the value of weighting n is varied.

FIG. 5 is a diagram showing group delay characteristics of the FIR filter when the value of weighting n is varied.

FIG. 6(a) is a diagram illustrating a structure of an asymmetry ratio determining circuit according to the present invention.

FIG. 6(b) is a diagram for explaining an operation of the asymmetry ratio determining circuit according to the present invention.

FIG. 7 is a diagram illustrating a structure of the asymmetry ratio update section according to the present invention.

FIG. 8 is a diagram illustrating a structure of an asymmetry ratio output section in the asymmetry ratio determining circuit according to the present invention.

FIG. 9 is a diagram illustrating a structure of a multiplier section according to the present invention.

FIG. 10 is a diagram illustrating a first structural example of a conventional recorded information reproducing apparatus.

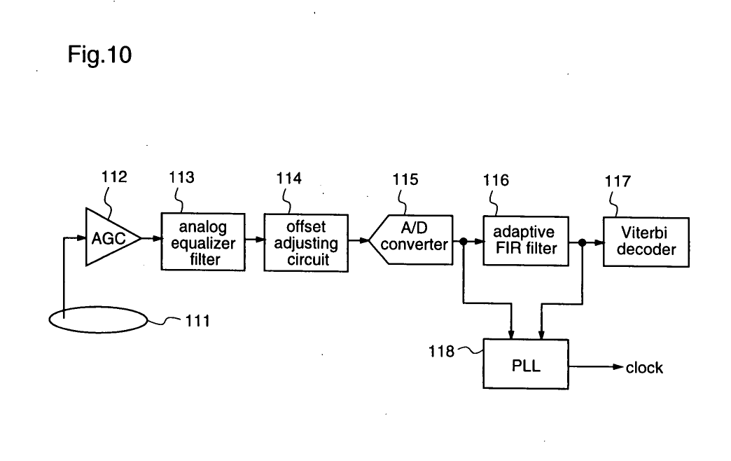

FIG. 11 is a diagram illustrating a second structural example of a conventional recorded information reproducing apparatus.

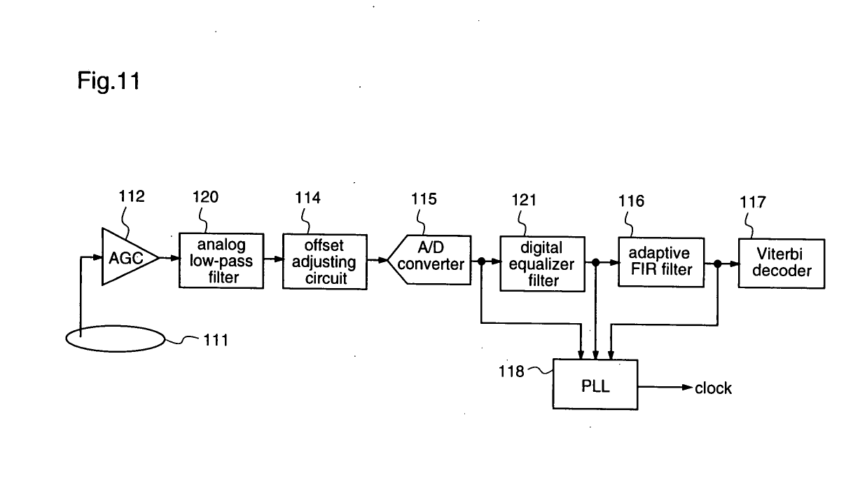

### DESCRIPTION OF NUMERALS

1 FIR filter
2 coefficient adjusting circuit
3 PLL
4 lock detector
5 jitter detector
11˜19, 21˜29 delay element
31˜39 multiplier
40 adder
201 asymmetry ratio determining circuit
202 multiplying section
301 jitter value capture section
302 controller section
303 minimum value detecting section
304 asymmetry ratio update section
305 asymmetry ratio output section
401 selector
402 comparator
403 adder
404 subtraction circuit
405 delay element
406˜408 delay element with enable terminal
409 AND circuit
501, 502 multiplexer
503 selection signal generating section
504, 505 multiplier
506, 507 de-multiplexer
511˜514, 516˜519 delay element
521 ˜524, 526˜529 delay element with enable terminal
601 timing adjusting register
602˜604, 606˜608 selector
605, 606 delay element
111 recording medium
112 AGC
113 analog equalizer filter
114 offset adjusting circuit
115 A/D converter
116 adaptive FIR filter
117 Viterbi decoder
118 PLL
120 analog low-pass filter
121 digital equalizer filter

### BEST MODE FOR CARRYING OUT THE INVENTION

### Embodiment 1

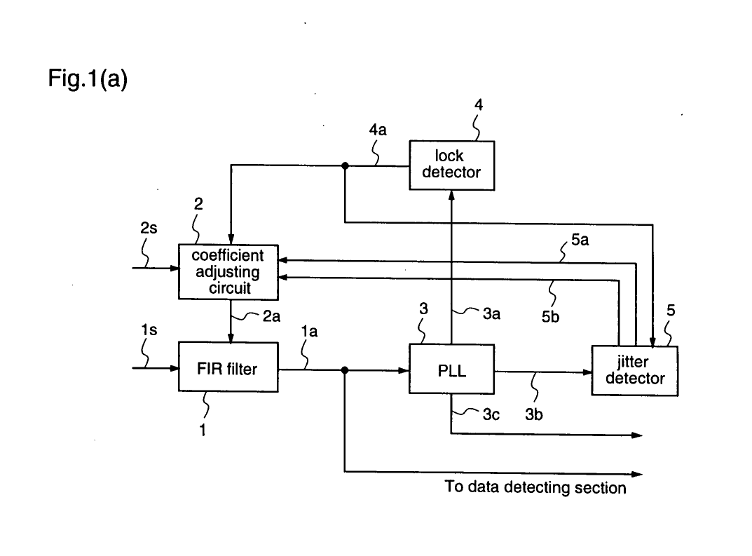

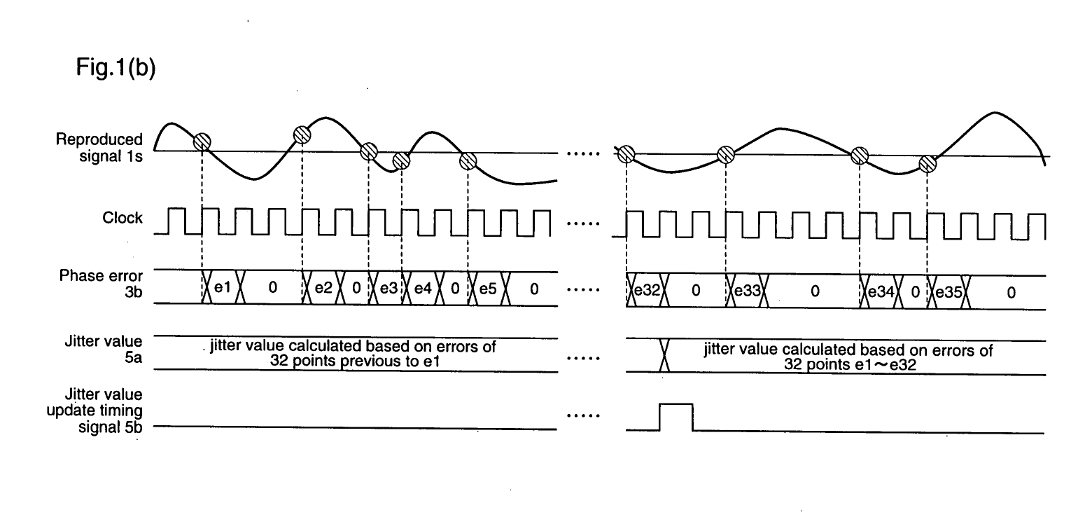

A filter coefficient adjusting circuit according to a first embodiment of the present invention will be hereinafter described, with reference to FIG. 1. FIG. 1(a) shows a structure of a filter coefficient adjusting circuit according to the first embodiment.

The filter coefficient adjusting circuit as shown in FIG. 1(a) comprises a FIR filter 1 which makes an inputted reproduced signal 1s subjected to a filtering processing employing an equalization coefficient, a PLL 3 which extracts clocks 3c which are synchronized with the reproduced signal on the basis of an output 1a of the FIR filter 1, a lock detector 4 which detects a lock state of the PLL 3, an equalization performance detecting means (jitter detector) 5 which detects an equalization performance of the FIR filter 1, and an equalization coefficient determining means (coefficient adjusting circuit) 2 which determines an equalization coefficient sequence 2a of the FIR filter 1 according to the output value 5a from the jitter detector 5.

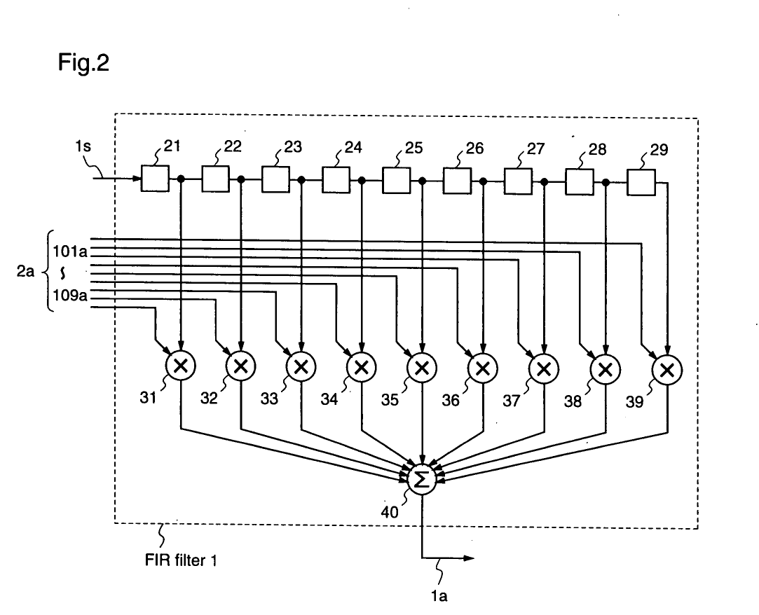

FIG. 2 is a diagram illustrating a detailed structure of the FIR filter 1 in the filter coefficient adjusting circuit of FIG. 1(a). In this embodiment, to simplify the explanations, the number of taps in the FIR filter 1 is assumed to be 9.

The FIR filter 1 includes delay elements 21˜29 each delaying the reproduced signal 1s by one clock, multipliers 31˜39 which respectively calculate the products of the respective outputs from the delay elements 21˜29 and equalization coefficients 101a˜109a (equalization coefficient sequence 2a) which are output from the coefficient adjusting circuit 2, and an adder 40 which calculates a sum of the outputs from the multipliers 31˜39.

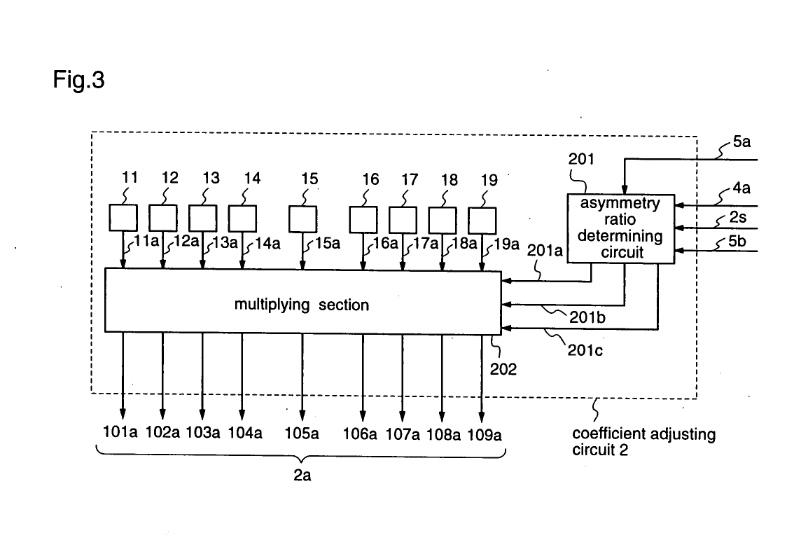

FIG. 3 is a diagram illustrating a detailed structure of the filter coefficient adjusting circuit 2 in the filter coefficient adjusting circuit of FIG. 1(a).

The coefficient adjusting circuit 2 includes delay elements 11˜19 which respectively retain initial values 11a˜19a of the equalization coefficient sequence 2a of the FIR filter 1, an asymmetry ratio determining circuit 201 which determines an asymmetry ratio of the equalization coefficient sequence 2a of the FIR filter 1, and a multiplier section 202 which multiplies the equalization coefficient initial values 11a˜19a which are retained in the delay elements 11˜19 by the asymmetry ratio which is determined by the asymmetry ratio determining circuit 201, thereby to generate new equalization coefficients 101a˜109a. Here, the equalization coefficient initial values 11a˜19a which are retained in the delay elements 11˜19 are set symmetrically with respect to the center tap of the FIR filter 1.

Next, the operation will be described.

An input reproduced signal 1s is equalized by the FIR filter 1, and the equalized signal 1a is outputted to the data detecting section (not shown) and the PLL 3. The PLL 3 extracts a synchronization clock 3c of the reproduced signal is from the output 1a of the FIR filter 1. At this time, the lock detector 4 monitors whether the PLL 3 is in a locked state or not, and when it detects that the PLL 3 is in a locked state, the lock detector 4 outputs a lock detection signal 4a to the coefficient adjusting circuit 2 and the jitter detector 5.

The jitter detector 5 accumulates a certain number of phase errors 3b which are detected by the PLL 3 during the clock extraction and takes a mean thereof, and calculates a jitter value 5a between the reproduced signal 1s and the extracted clock 3c. The calculating process will be shown in FIG. 1(b) In this figure, the accumulation number of the phase errors 3b is taken as 32. Since generally phase errors are calculated based on a zero cross point of the reproduced signal, the jitter value is updated for each time 32 zero cross points are detected. In addition, a jitter value update timing signal 5b indicating the update timing of the jitter value is generated.

The coefficient adjusting circuit 2 captures the jitter value 5a which is output from the jitter detector 5 on the basis of the jitter value update timing signal 5b, while it adjusts the equalization coefficient sequence 2a of the FIR filter 1 so as to minimize the value.

Here, an equalization coefficient adjusting method by the coefficient adjusting circuit 2 will be described in more detail.

First, the asymmetry ratio determining circuit 201 captures the jitter value 5a which is output from the jitter detector 5 at the jitter value update timing 5b, and determines an asymmetry ratio of the equalization coefficient sequence 2a of the FIR filter 1 so that the jitter value 5a is minimized. The asymmetry ratio represents a ratio between the multiplier factor 201a for the right half and the multiplier factor 201b for the left half, with respect to the center tap of the FIR filter 1, as n: (2−n) (where “n” is a real number which is equal to 0 or larger and equal to 2 or smaller).

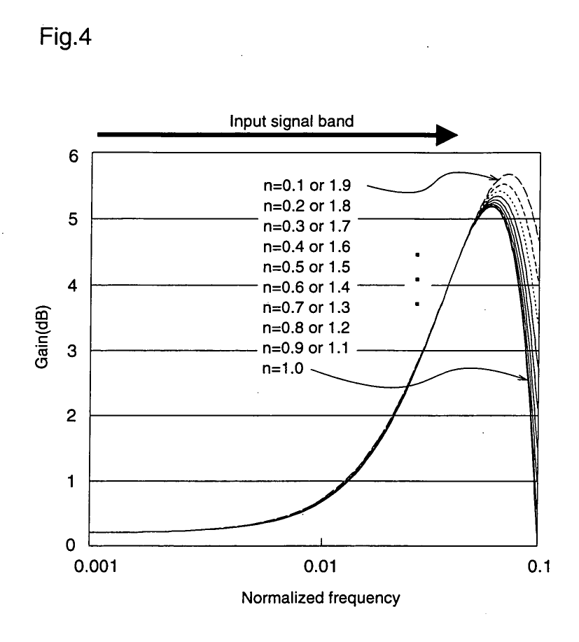

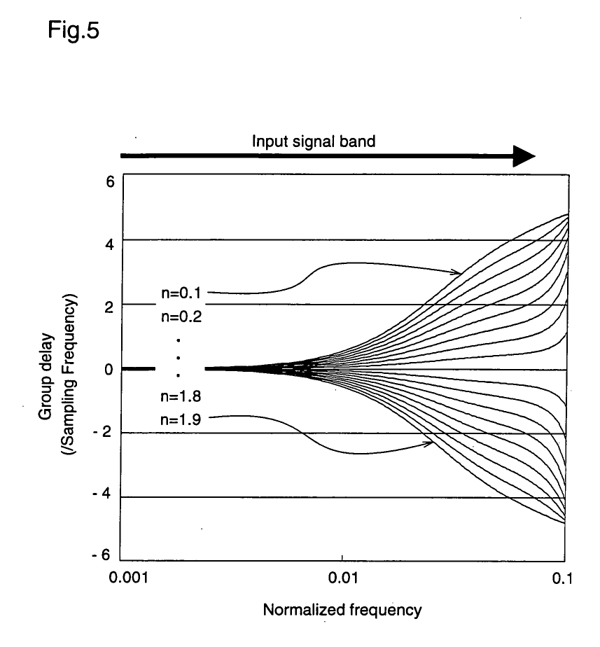

The multiplier section 202 multiplies the equalization coefficient initial values 11a˜14a which are which are retained in the delay elements 11˜14 on the left half among the delay elements 11˜19 by a factor n, and multiplies the equalization coefficient initial values 16a˜19a which are retained in the delay elements 16˜19 on the right half by a factor of (2−n), on the basis of the determined asymmetry ratio. FIG. 4 shows gain characteristics of the FIR filter 1 at a time when the value of weighting n (the asymmetry ratio) is varied. The group delay characteristics of the FIR filter 1 at that time is shown in FIG. 5. As can be seen from these figures, by varying the value of weighting n, the group delay characteristics in a wide band portion can be adjusted, with giving almost no changes to the gain characteristics.

Besides, until the lock detector 4 detects the lock state of the PLL 3, i.e., before the PLL 3 gets in a locked state, the asymmetry ratio determining circuit 201 makes the value of weighting as n=1, and controls such that as the equalization coefficient sequence 2a, the initial values which are previously set, i.e., the equalization coefficient initial values 11a˜19a which are retained in the delay elements 11˜19 are outputted. Thereby, it is possible to maintain the stability of the lock-in operation of the PLL 3.

The first embodiment as described above includes the FIR filter 1 which carries out a filtering processing according to an equalization processing to an inputted reproduced signal, the PLL 3 which extracts clocks synchronized with the reproduced signal using the output from the FIR filter 1, the jitter detector 5 which detects the equalization performance of the FIR filter 1, and the coefficient adjusting circuit 2 which updates the equalization coefficient of the FIR filter 1 according to the output value from the jitter detector 5. Therefore, it is possible to carry out a simple control within the circuit, as well as optimize the group delay of the reproduced signal according to characteristics of the reproduced signal, without providing any additional circuits, and thereby, the reproduction performance can be improved.

In addition, since the coefficient adjusting circuit 2 weights the initial values of the equalization coefficients corresponding to the left side with respect to the center tap of the FIR filter 1, when the number of taps in the FIR filter 1 is an odd number, by a factor of n (n is a real number which is equal to 0 or larger and equal to 2 or smaller), and weights the initial values of the equalization coefficients corresponding to the right side, by a factor of (2−n), to output the weighted values. Therefore, it is possible to control only the amount of group delay, with giving no changes to the gain characteristics of the FIR filter 1.

### Embodiment 2

A filter coefficient adjusting circuit according to a second embodiment of the present invention will be described hereinafter, with reference to FIGS. 1-3 and FIGS. 6-7. Since FIGS. 1-3 are described in the first embodiment, the explanations thereof are omitted here.

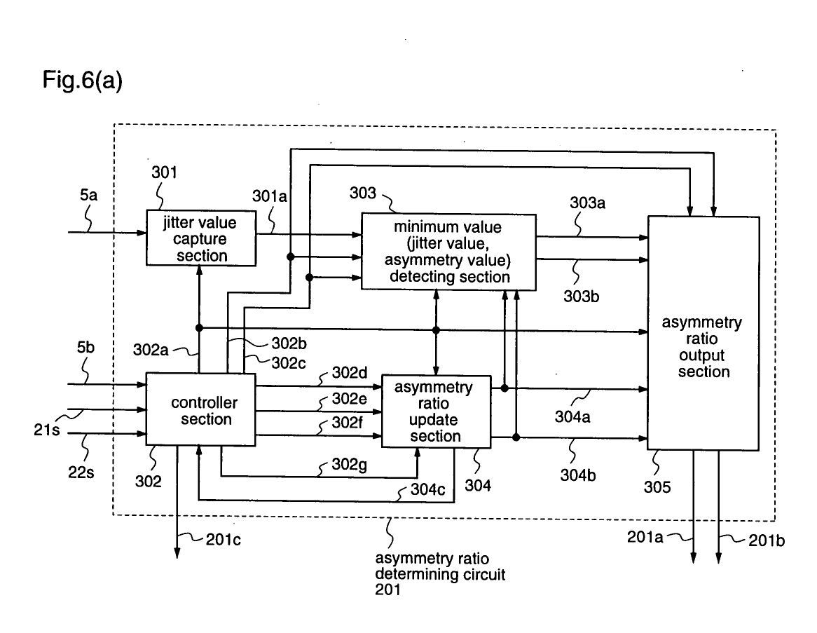

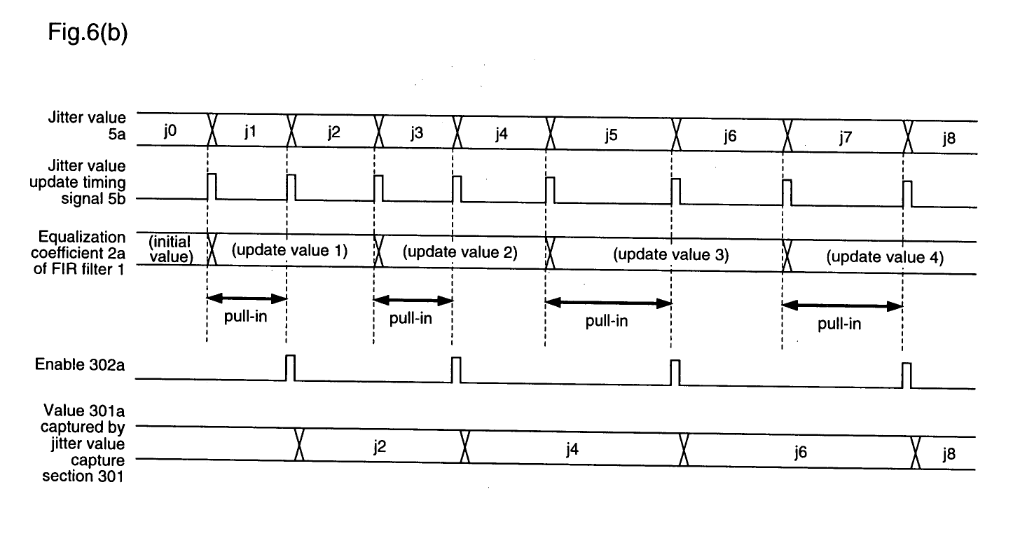

FIG. 6(a) is a diagram illustrating a detailed structure of the asymmetry ratio determining circuit 201 in the coefficient adjusting circuit 2 of FIG. 3.

The asymmetry ratio determining circuit 201 as shown in FIG. 6(a) includes a jitter value capturing section 301 which captures a jitter value 5a which is outputted from the jitter detector 5, a controller section 302 which generates a control signal within the coefficient adjusting circuit 2, a minimum value detecting section 303 which detects the minimum value of the jitter values 301a which are captured into the jitter value capture section 301 and retains an asymmetry ratio at that time, an asymmetry ratio update section 304 which updates the asymmetry ratio according to outputs 302d-302g from the controller section 302, and an asymmetry ratio output section 305 which selects one among the asymmetry ratio which are retained in the minimum value detecting section 303, the asymmetry ratio which is updated by the asymmetry ratio update section 304, and the initial value, to output the selected value.

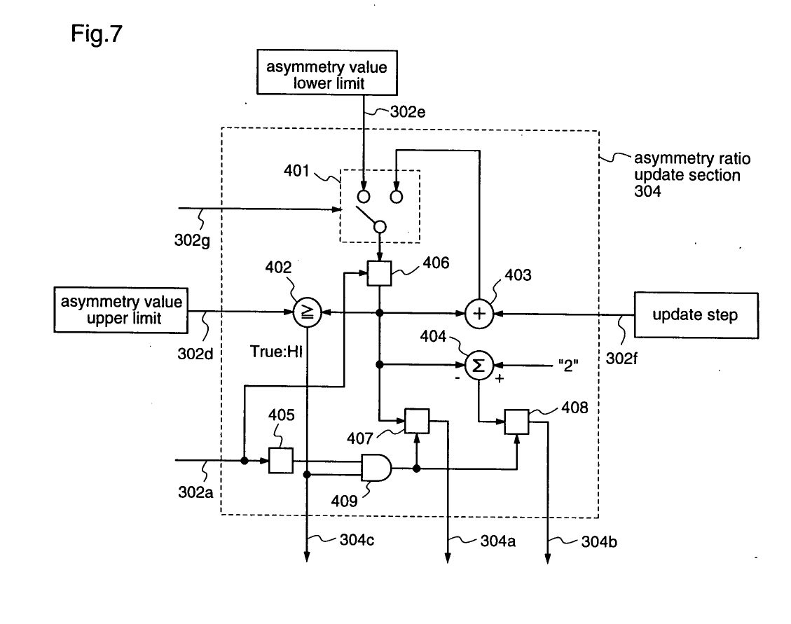

FIG. 7 is a diagram illustrating a detailed structure of the asymmetry ratio update section 304 shown in FIG. 6(a).

The asymmetry ratio update section 304 includes a selector 401, a comparator 402, an adder 403, a subtracter 404, a delay element 405, delay elements with enable terminals 406˜408, and an AND circuit 409.

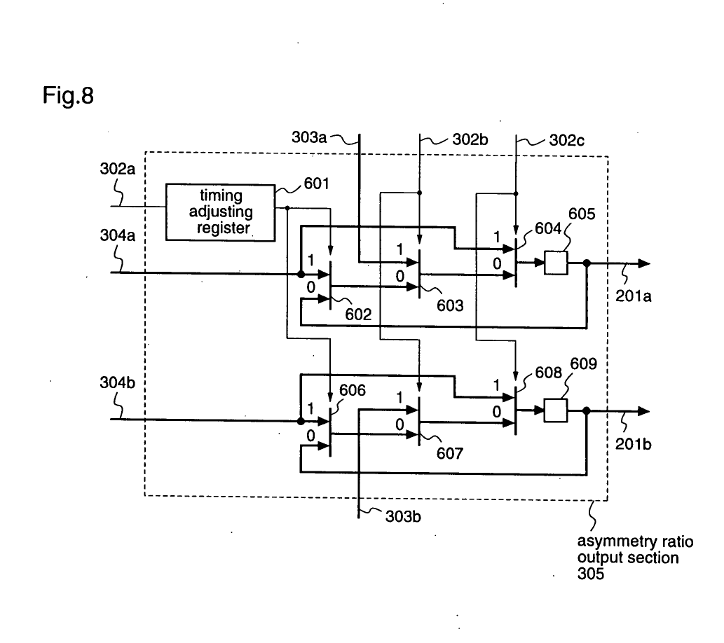

FIG. 8 is a diagram illustrating an example of a detailed structure of the asymmetry ratio output section 305 shown in FIG. 6(a).

The asymmetry ratio output section 305 includes a timing adjusting register 601, selectors 602˜604 and 606˜608, and delay elements 605 and 609, and outputs an asymmetry ratio in accordance with an enable signal 302a, a learning complete signal 302b, and a reset signal 302c. That is, the asymmetry ratio output section 305 selects updated asymmetry values 304a and 304b which are outputted from the asymmetry ratio update section 304 during a period of learning the asymmetry ratio, selects asymmetry values 303a and 303b which are outputted from the minimum value detecting section 303 at completing the learning, and selects the initial value (the value of weighting n=1) when the reset signal 302c is inputted, to output the selected value.

Next, the method of determining the asymmetry ratio by the asymmetry ratio determining circuit 201 will be described.

The controller section 302 generates an enable signal 302a on the basis of the jitter value update timing signal 5b which is output from the jitter detector 5.

A timing chart of the jitter value capturing section 301 is shown in FIG. 6(b). While as already described in the first embodiment the jitter value 5a is generated by accumulating a predetermined number of phase errors 3b and averaging those, when the equalization coefficient sequence 2a of the FIR filter 1 is updated, the group delay characteristics of the FIR filter 1 varies, and the PLL 3 attempts to follow the variations of the characteristics. Thus, while the PLL 3 remains its locked state, the PLL 3 performs a pull-in operation so as to become a stationary state. Therefore, it is considered that there occurs variation in the jitter value 5a until the PLL 3 enters into a stationary state.

Thus, when the equalization coefficient sequence 2a of the FIR filter 1 is updated, the controller section 302 generates an enable signal 302a to be outputted to the jitter value capture section 301 so that the jitter values (j1, j3, j5, j7) immediately after updating the equalization coefficient sequence 2a are not captured. Then, the jitter value capture section 301 captures the jitter values (j2, j4, j6, j8) on the basis of the enable signal 302a.

As described above, when the equalization coefficient sequence 2a is updated, the enable signal 302a is generated so that the jitter value 5a is captured by the jitter value capture section 301 after the jitter value 5a has become a stationary value. Therefore, the variations in the jitter values due to the pulling-in operation of the PLL 3 can be prevented by delaying the timings of pulling in the jitter values. Here, while the interval of pulling-in operation in the PLL 3 is made 1, the same effects can be obtained even when the interval is equal to 2 or larger. That is, it is possible to obtain a more accurate jitter value by capturing the jitter value after a certain amount of time has elapsed after the equalization coefficient sequence 2a is updated.

The controller section 302 outputs an upper limit 302d and a lower limit 302e as asymmetry values, and an update step 302f by the input of a learning setting control signal 21s as an external signal. Further, it outputs an initialization signal 302g to the asymmetry ratio update section 304, and a reset signal 302c to the minimum value detecting section 303 and the asymmetry ratio output section 305 by the input of an operation setting control signal 22s. Further, when a search conclusion signal 304c is outputted from the asymmetry ratio update section 304, a learning completion signal 302b is outputted from the controller section 302 to the minimum value detecting section 303 and the asymmetry ratio output section 305.

In the asymmetry ratio update section 304, when the initialization signal 302g which is outputted from the controller section 302 is High, the asymmetrical lower limit 302e is outputted from the controller section 302 is selected by the selector 401. Then, the asymmetrical lower limit value 302e which is outputted from the selector 401 is captured by the delay element with an enable terminal 406, on the basis of the enable signal 302a which is outputted from the controller section 302 at a timing of capturing the jitter value. This delay element with an enable terminal 406 takes the captured asymmetrical lower limit value 302e as an initial value, increments (updates) the equalization coefficient by the update step (update interval) 302f at each timing when the jitter value is captured, i.e., at each timing when the enable signal 302a becomes High, and this updated value is captured into the delay elements with an enable terminal 407 and 408. Here, the comparator 402 compares the output from the delay element with an enable terminal 406 and the asymmetrical upper limit value 302d which is outputted from the controller section 302 with each other. When the output from the delay element with an enable terminal 406 is higher than the asymmetrical upper limit value 302d, the comparator 402 outputs a search conclusion signal 304c indicating the search for asymmetrical value has concluded.

The minimum value detecting section 303 detects the minimum value among the jitter values 301a which are captured by the jitter value capture section 301 at timings when the enable signal 302a which is outputted from the controller section 302 changes from Low to High, and retains the minimum value and a value of the asymmetry ratio at that time. In addition, when a reset signal 302c is outputted from the controller section 302, the minimum value and the asymmetry ratio at that time, which are retained therein, are reset.

The asymmetry ratio output section 305 detects the minimum value among the jitter value 301a which are captured into the jitter capture section 301 at a timing when the enable signal 302 which is outputted from the controller section 302 becomes High from Low, and retains the value and the asymmetric value at that time.

The asymmetry ratio output section 305 outputs the asymmetry ratio as n=1, when the reset signal 302c which is outputted from the controller section 302 is High, and outputs an asymmetry ratio which makes the jitter values 303a and 303b which are outputted from the minimum value detecting section 303 be minimum, when the learning conclusion signal 302b which is outputted from the controller section 302 is High, and outputs the update values 304a and 304b of the asymmetry ratio which are outputted from the asymmetry ratio update section 304 otherwise.

In this second embodiment, the asymmetry ratio determining circuit 201 includes the jitter value capture section 301 which captures the jitter value which is outputted from the jitter detector 5, the controller section 302 which generates a control signal within the coefficient adjusting circuit 2, the minimum value detecting section 303 which detects the minimum value among the jitter values which are captured by the jitter value capture section 301 and retains a value of the asymmetry ratio at that time, the asymmetry ratio update section 304 which updates the asymmetry ratio according to the output from the controller section 302, and the asymmetry ratio output section 305 which selects one among the asymmetry value which is held in the minimum value detecting section 303, the asymmetry value updated by the asymmetry ratio update section 304, and the initial value, to output the selected value. Therefore, it is possible to determine the asymmetry ratio which can minimize the jitter value within a previously-set asymmetry ratio range, and thereby the reproduction performance is improved.

While in this second embodiment, the coefficient adjusting circuit 2 carries out a learning operation of the equalization coefficient at a timing when the reset signal which is outputted from the controller section 302 to the minimum value detecting section 303, the asymmetry ratio update section 304, and the asymmetry ratio output section 305 changes from High to Low, by generating the reset signal utilizing an operation setting control signal which is inputted to the controller section 302 according to the characteristics of the reproduced signal, it is possible to carry out the group delay adjustment more efficiently.

For example, when data are reproduced from a recording medium in which, as in a writable DVD, data is recorded with divided in sector units, there may be cases where the reproduction characteristics of data which are recorded in the medium differ for each sector. That is, there may be cases where the optimum values of the asymmetry ratio for the equalization coefficient of the FIR filter 1 are different. Accordingly, by inputting a gate signal which is synchronized with a sector to the controller section 302 as a control signal (as an operation setting control signal) and generating a reset signal based on the gate signal, it is possible to obtain the optimum value of the group delay for each sector. Further, when a defect or the like occurs in the reproduced signal, by carrying out re-learning by generating a reset signal employing a defect detection signal, it is possible to further enhance the reliability in correction of the group delay.

### Embodiment 3

A filter coefficient adjusting circuit according to a third embodiment of the present invention will be hereinafter described, with reference to FIGS. 1˜3 and 9. As FIGS. 1˜3 have been already described in the first embodiment, the explanations thereof are omitted here.

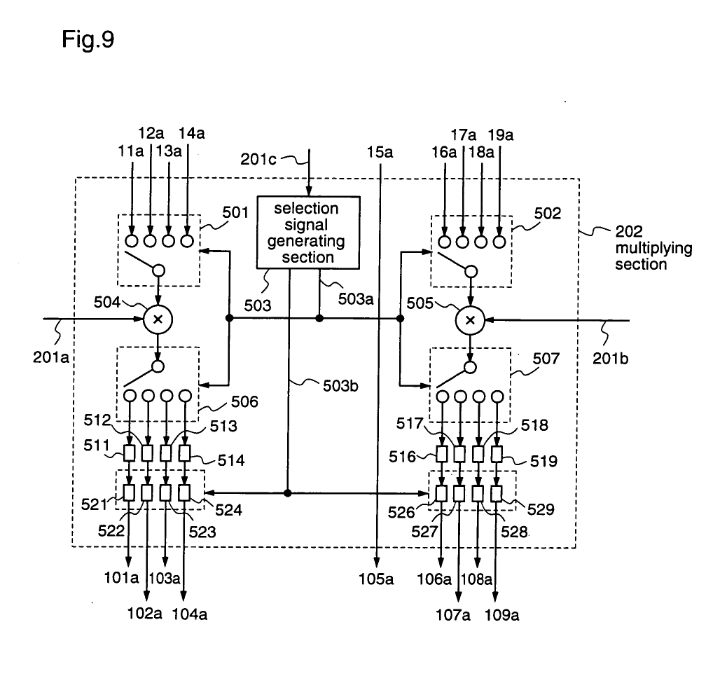

FIG. 9 is a diagram illustrating a structure of the multiplier section 202 in the coefficient adjusting circuit 2 in FIG. 3.

The multiplier section 202 as shown in FIG. 9 includes a selection signal generating section 503 which generates a select signal 503a and an enable signal 503b on the basis of the timing signal 201c which is outputted from the asymmetry ratio determining circuit 201, a multiplexer 501 which selects one among equalization coefficient initial values 11a˜14a on the basis of the select signal 503a, a multiplexer 502 which selects one among equalization coefficient initial values 15a˜19a on the basis of the select signal 503a, a multiplier 504 which multiplies the output from the multiplexer 501 by the asymmetry value 201a, a multiplier 505 which multiplies the output from the multiplexer 52 by the asymmetry value 201b, a de-multiplexer 506 which connects the output from the multiplier 504 to one of delay elements 511˜514 at the latter stage on the basis of the select signal 503a, a de-multiplexer 507 which connects the output from the multiplier 505 to one of delay elements 516˜519 at the latter stage on the basis of the select signal 503a, delay elements 511˜514 which store the values which are outputted from the de-multiplexer 506, delay elements 516˜619 which store the values which are outputted from the de-multiplexer 507, delay elements with enable terminals 521˜524 which update retained equalization coefficients to the value stored in the delay elements 511˜514 on the basis of the enable signal 503b, and delay elements with enable terminals 526˜529 which update a retained equalization coefficient to the values which are stored in the delay elements 516˜519 on the basis of the enable signal 503b, and detects update timing of the asymmetry ratio on the basis of the timing signal 201c which is outputted from the asymmetry ratio determining circuit 201, and utilizes the inputted data on time sharing, thereby generating a new equalization coefficient sequence 2a. That is, it outputs those which are obtained by weighting the equalization coefficient initial values 11a˜14a by a factor of n as equalization coefficients 101a˜104a, the equalization coefficient initial value 15a as an equalization coefficient 105a, and those which are obtained by weighting the equalization coefficient initial values 16a˜19a by a factor of (2−n) as equalization coefficients 106a˜109a, to the FIR filter 1.

Next, the operation of the multiplier section 202 will be described.

When the asymmetry ratio is set so as to be symmetrical with respect to the center tap 25 of the FIR filter 1, the selection signal generating section 503 carries out output control of the multiplexers 501 and 502 and the de-multiplexers 506 and 507 using a select signal 503a, and stores those which are obtained by weighting the equalization coefficient initial values 11a˜14a by a factor of n in the delay elements 511˜514, and stores those which are obtained by weighting the equalization coefficient initial values 16a˜19a by a factor of (2−n) in the delay elements 516˜519, respectively.

When the storage of values into the delay elements 511˜514 and into the delay elements 516˜519 are concluded, the update of equalization coefficients which are held collectively is carried out by the inputting of the enable signal 503b, and the updated equalization coefficients are outputted as new equalization coefficients 101a˜104a and 106a˜109a. Here, the equalization coefficient corresponding to the delay element 25 of the FIR filter 1 remains as the initial value.

In this way, it is possible to carry out the group delay correction by repeatedly conducting the update of the equalization coefficients and detecting the asymmetry ratio which makes the jitter value the minimum.

Further, it is possible to make a pair comprising two delay elements which are at equal distances from the delay element 25 of the FIR filter 1, and to establish an asymmetry ratio independently for each pair. For example, initially an optimum value for the asymmetry ratio for a pair of delay elements 21 and 29 in the FIR filter 1 is detected, next an optimum value for the asymmetry ratio for a pair of delay elements 22 and 28 is detected, and similar operations are repeatedly conducted for remaining all pairs. Thus, a further high preciseness group delay adjustment can be performed.

In this third embodiment, the multiplier section 202 includes the multiplexers 501 and 502, the selection signal generating section 503 which generates a select signal 503a as well as an enable signal 503b on the basis of the timing signal 201c which is output from the asymmetry ratio determining circuit 201, the multipliers 504 and 505, the de-multiplexers 506 and 507, the delay elements 511˜514 and 516˜519, and the delay elements with enable terminal 521˜524 and 526˜529, and the update timing of the asymmetry ratio is detected on the basis of the timing signal 201c which is outputted from the asymmetry ratio determining circuit 201, and the inputted data is used on time sharing thereby to generate a new equalization coefficient sequence. Therefore, the filter coefficient of the FIR filter 1 can be set symmetrically with respect to the center tap, and consequently, the filter coefficient can be updated with giving almost no changes to the gain characteristics of the FIR filter 1.

In the first to third embodiments, the descriptions are given of a case where the number of taps in the FIR filter is 9, i.e., an odd number. However, even in cases where the number of taps is an even number (this corresponds to a case where there is no center tap), the same effects as in the above embodiments are also obtained. When the tap number in the FIR filter 1 is an even number, the coefficient adjusting circuit 2 weights the initial value of the equalization coefficient on the left with respect to the center of the delay line of the FIR filter 1 by a factor of n (n is a real number that is 0 or larger and 2 or smaller) and weights the initial value of the equalization coefficient on the right by a factor of (2−n), output the weighted values.

In the first to third embodiments, the descriptions are given of cases where the jitter detector 5 which detects jitters between the output from the FIR filter 1 and the synchronization clock which is extracted by the PLL 3 is employed as the equalization performance detecting means. However, it goes without saying that the same function can be implemented by using an equalization error detecting means or the like.

### INDUSTRIAL AVAILABILITY

A reproduced signal processing apparatus according to the present invention is useful as a delay correcting circuit which can adjust the equalization coefficient of the FIR filter so that the jitter value becomes the minimum.

1. A filter coefficient adjusting circuit comprising:
an FIR filter which makes an input signal subjected to a filtering process according to an equalization coefficient;
a PLL which extracts a clock synchronized with the input signal, using an output from the FIR filter;
an equalization performance detecting unit that detects an equalization performance of the FIR filter; and
an equalization coefficient determining unit that weights the previously-set equalization coefficient of the FIR filter, for left and right taps, with respect to a center tap when the number of taps in the FIR filter is an odd number, and with respect to a central delay line when the number of taps in the FIR filter is an even number, according to an output value of the equalization performance detecting unit, and outputs the weighted value.

2. The filter coefficient adjusting circuit as defined in claim 1 wherein
the equalization coefficient determining unit weights the equalization coefficient of the FIR filter symmetrically, with respect to a center tap when the number of taps in the FIR filter is an odd number, and with respect to a central delay line when the number of taps in the FIR filter is an even number, before the PLL reaches the locked state.

3. The filter coefficient adjusting circuit as defined in claim 1 wherein
the equalization coefficient determining unit weights, while the tap coefficient of the FIR filter is an odd number, the initial value of the equalization coefficient at left with respect to a center tap of the FIR filter by a factor of n (n is a real number which is equal to 0 or larger and equal to 2 or smaller), and weights the initial value of the equalization coefficient at right by a factor of (2−n), thereby to output the weighted value.

4. The filter coefficient adjusting circuit as defined in claim 1 wherein
the equalization coefficient determining unit weights, while the tap coefficient of the FIR filter is an even number, the initial value of the equalization coefficient at left with respect to a center of a delay line of the FIR filter by a factor of n (n is a real number which is equal to 0 or larger and equal to 2 or smaller), and weights the initial value of the equalization coefficient at right by a factor of (2−n), thereby to output the weighted value.

5. The filter coefficient adjusting circuit as defined in claim 3 wherein
the value of weighting n is independently set for each pair consisting of two taps which are at equal distances from the center tap of the FIR filter.

6. The filter coefficient adjusting circuit as defined in claim 4 wherein
the value of weighting n is independently set for each pair consisting of two taps which are at equal distances from the center of the delay line of the FIR filter.

7. The filter coefficient adjusting circuit as defined in claim 3 wherein
the equalization coefficient determining unit determines an optimum output value of the equalization performance detecting unit, and determines the value of weighting n which provides an optimum output value of the equalization performance detecting unit.

8. The filter coefficient adjusting circuit as defined in claim 7 wherein
the equalization coefficient determining unit captures the output of the equalization performance detecting unit at variable time intervals, and determines the value of weighting n on the basis of the captured value.

9. The filter coefficient adjusting circuit as defined in claim 7 wherein
the equalization coefficient determining unit establishes an upper limit and a lower limit and an update interval thereof, independently, for the value of weighting n, and determines the value of weighting n within the established range.

10. The filter coefficient adjusting circuit as defined in claim 7 wherein
the equalization coefficient determining unit establishes an operation of detecting the value of weighting n which provides an optimum output value of the equalization performance detecting unit on the basis of the operation setting control signal in accordance with the characteristics of the input signal.

11. The filter coefficient adjusting circuit as defined in claim 4 wherein
the equalization coefficient determining unit determines an optimum output value of the equalization performance detecting unit, and determines the value of weighting n which provides an optimum output value of the equalization performance detecting unit.

12. The filter coefficient adjusting circuit as defined in claim 11 wherein
the equalization coefficient determining unit captures the output of the equalization performance detecting unit at variable time intervals, and determines the value of weighting n on the basis of the captured value.

13. The filter coefficient adjusting circuit as defined in claim 11 wherein
the equalization coefficient determining unit establishes an upper limit and a lower limit and an update interval thereof, independently, for the value of weighting n, and determines the value of weighting n within the established range.

14. The filter coefficient adjusting circuit as defined in claim 11 wherein
the equalization coefficient determining unit establishes an operation of detecting the value of weighting n which provides an optimum output value of the equalization performance detecting unit on the basis of the operation setting control signal in accordance with the characteristics of the input signal.

15. The filter coefficient adjusting circuit as defined in claim 5 wherein
the equalization coefficient determining unit determines an optimum output value of the equalization performance detecting unit, and determines the value of weighting n which provides an optimum output value of the equalization performance detecting unit.

16. The filter coefficient adjusting circuit as defined in claim 15 wherein
the equalization coefficient determining unit captures the output of the equalization performance detecting unit at variable time intervals, and determines the value of weighting n on the basis of the captured value.

17. The filter coefficient adjusting circuit as defined in claim 15 wherein
the equalization coefficient determining unit establishes an upper limit and a lower limit and an update interval thereof, independently, for the value of weighting n, and determines the value of weighting n within the established range.

18. The filter coefficient adjusting circuit as defined in claim 15 wherein
the equalization coefficient determining unit establishes an operation of detecting the value of weighting n which provides an optimum output value of the equalization performance detecting unit on the basis of the operation setting control signal in accordance with the characteristics of the input signal.

19. The filter coefficient adjusting circuit as defined in claim 6 wherein
the equalization coefficient determining unit determines an optimum output value of the equalization performance detecting unit, and determines the value of weighting n which provides an optimum output value of the equalization performance detecting unit.

20. The filter coefficient adjusting circuit as defined in claim 19 wherein
the equalization coefficient determining unit captures the output of the equalization performance detecting unit at variable time intervals, and determines the value of weighting n on the basis of the captured value.

21. The filter coefficient adjusting circuit as defined in claim 19 wherein
the equalization coefficient determining unit establishes an upper limit and a lower limit and an update interval thereof, independently, for the value of weighting n, and determines the value of weighting n within the established range.

22. The filter coefficient adjusting circuit as defined in claim 19 wherein
the equalization coefficient determining unit establishes an operation of detecting the value of weighting n which provides an optimum output value of the equalization performance detecting unit on the basis of the operation setting control signal in accordance with the characteristics of the input signal.
